(19) United States
(12) Patent Application Publication
(10) Pub. No.: US 2013/0270634 A1
(43) Pub. Date: Oct. 17, 2013

(54) HIGH VOLTAGE DEVICE AND MANUFACTURING METHOD THEREOF

(71) Applicants: Tsung-Yi Huang, Hsinchu City (TW); Chien-Wei Chiu, Beigang Township (TW)

(72) Inventors: Tsung-Yi Huang, Hsinchu City (TW); Chien-Wei Chiu, Beigang Township (TW)

(73) Assignee: Richtek Technology Corporation

(21) Appl. No.: 13/445,151

(22) Filed: Apr. 12, 2012

(51) Int. Cl. H01L 29/78; H01L 21/336

(52) U.S. Cl. 257/336; 438/294; 257/E29.257; 257/E21.409

(57) ABSTRACT

The present invention discloses a high voltage device and a manufacturing method thereof. The high voltage device is formed in a first conductive type substrate. A low voltage device is also formed in the substrate. The high voltage device includes a drift region, a gate, a source, a drain, and a mitigation region. The mitigation region has a second conductive type, and is formed in the drift region between the gate and drain. The mitigation region is formed by a process step which also forms a lightly doped drain (LDD) region in the low voltage device.

### BACKGROUND OF THE INVENTION

1. Field of Invention

The present invention relates to a high voltage device and a manufacturing method of a high voltage device; particularly, it relates to such device and a manufacturing method thereof wherein a mitigation region is formed by a process step which is required in forming a low voltage device.

2. Description of Related Art

FIG. 1 shows a cross-section view of a prior art horizontal double diffused metal oxide semiconductor (LDMOS) device 100. As shown in FIG. 1, a P-type substrate 11 has multiple isolation regions 12 by which the LDMOS device 100 is electrically isolated from other devices in the substrate 11. The isolation region 12 for example is formed by a shallow trench isolation (STI) process or a local oxidation of silicon (LOCOS) process, the latter being shown in the figure. The LDMOS device 100 includes a gate 13, an N-type drift region 14, an N-type source 15, an N-type drain 16, a P-type body region 17, and a P-type body electrode 18. The N-type drift region 14, the N-type source 15, and the N-type drain 16 are formed by lithography process steps and ion implantation process steps, wherein the lithography process steps define the implantation regions by a photoresist mask and/or together with a self-alignment effect provided by all or part of the gate 13 and the isolation regions 12, and the ion implantation process steps implant N-type impurities to the defined regions in the form of accelerated ions. The P-type body region 17 and the P-type body electrode 18 are formed by lithography process steps and ion implantation process steps, wherein the lithography process steps define the implantation regions by a photoresist mask and/or together with a self-alignment effect provided by all or part of the gate 13 and the isolation regions 12, and the ion implantation process steps implant P-type impurities to the defined regions in the form of accelerated ions. The source 15 and the drain 16 are beneath the gate 13 and at different sides thereof respectively. Part of the gate 13 is above a field oxide region 12a in the LDMOS device 100.

FIG. 2 shows a cross-section view of a prior art double diffused drain metal oxide semiconductor (DDDMOS) device 200. The DDDMOS device 200 is different from the aforementioned prior art LDMOS device 100 in that, a gate 23 is entirely above the surface of the P-type substrate 11 without any part above an isolation region 22. As shown in FIG. 2, the P-type substrate 11 has multiple isolation regions 22 by which the DDDMOS device 200 is electrically isolated from other devices in the substrate 11. The isolation region 22 for example is formed by the STI process or the LOCOS process, the former being shown in the figure. The DDDMOS device 200 includes a gate 23, an N-type drift region 24, an N-type source 25, an N-type drain 26, an N-type isolation region 29, a P-type well 27, and a P-type body electrode 28. The N-type drift region 24, the N-type source 25, the N-type drain 26, and the N-type isolation region 29 are formed by lithography process steps and ion implantation process steps, wherein the lithography process steps define the implantation regions by photoresist masks and/or together with a self-alignment effect provided by all or part of the gate 23 and the isolation regions 22, and the ion implantation process steps implant N-type impurities to the defined regions in the form of accelerated ions. The P-type well region 27 and the P-type body electrode 28 are formed by lithography process steps and ion implantation process steps, wherein the lithography process steps define the implantation regions by photoresist masks and/or together with a self-alignment effect provided by all or part of the gate 23 and the isolation regions 22, and the ion implantation process steps implant P-type impurities to the defined regions in the form of accelerated ions. The source 25 and the drain 26 are beneath the gate 23 and at different sides thereof respectively.

The LDMOS device and the DDDMOS device are high voltage devices designed for applications requiring higher operation voltages. However, if it is required for the LDMOS device or the DDDMOS device to be integrated with a low voltage device in one substrate, the high voltage device and the low voltage device should adopt common manufacturing process steps with the common ion implantation parameters, and thus the flexibility of the ion implantation parameters for the LDMOS device or the DDDMOS device is limited; as a result, the LDMOS device or the DDDMOS device will have a lower breakdown voltage and therefore a limited application range. To increase the breakdown voltage of the LDMOS device and the DDDMOS device, additional manufacturing process steps are required, that is, an additional lithography process and an additional ion implantation process are required in order to provide different ion implantation parameters, but this increases the cost.

In view of above, to overcome the drawbacks in the prior art, the present invention proposes a high voltage device and a manufacturing method thereof which provide a higher breakdown voltage so that the high voltage device may have a broader application range, in which additional manufacturing process steps are not required such that the high voltage device can be integrated with and a low voltage device and manufactured by common manufacturing process steps.

### SUMMARY OF THE INVENTION

The first objective of the present invention is to provide a high voltage device.

The second objective of the present invention is to provide a manufacturing method of a high voltage device.

To achieve the objectives mentioned above, from one perspective, the present invention provides a high voltage device, which is formed in a first conductive type substrate on which is formed a low voltage device, wherein the substrate has an upper surface. The high voltage device includes: adrift region formed beneath the upper surface, and doped with second conductive type impurities; agate formed on the upper surface, wherein at least part of the drift region is formed below the gate; a source and a drain, doped with the second conductive type impurities, and formed beneath the upper surface at different sides of the gate, wherein the drain is located in the drift region, and the drain and the gate are separated by a portion of the drift region; and a mitigation region, doped with the second conductive type impurities, and formed in the drift region, wherein the mitigation region is located between the gate and the drain, and the mitigation region is formed by a process step which also forms a lightly doped (LDD) region in the low voltage device.

From another perspective, the present invention provides a manufacturing method of a high device, including: providing a first conductive type substrate for forming the high voltage device and a low voltage device in the substrate, wherein the substrate has an upper surface; forming a second conductive type drift region beneath the upper surface; forming a gate on the upper surface, wherein at least part of the drift region is formed below the gate; forming second conductive type source and drain beneath the upper surface at different sides of the gate, wherein the drain is located in the drift region, and the drain and the gate are separated by a portion of the drift region; and forming a second conductive type mitigation region beneath the upper surface in the drift region, wherein the mitigation region is located between the gate and the drain, and the mitigation region is formed by a process step which also forms a lightly doped (LDD) region in the low voltage device.

In one preferable embodiment of the high voltage device, the low voltage device further includes: a low voltage gate formed on the upper surface; and a low voltage source and a low voltage drain, doped with the second conductive type impurities, and formed beneath the upper surface at different sides of the low voltage gate, wherein the low voltage source and/or the low voltage drain are/is located in the LDD region from top view; wherein the LDD region is for mitigating a hot carrier effect of the low voltage device in operation.

In another embodiment of the high voltage device, the high voltage device preferably further includes a second conductive type isolation region formed beneath the upper surface, wherein the drift region, the source, the drain, and the mitigation region are located in the isolation region; and a first conductive type well formed in the isolation region, wherein the isolation region is separated from the drift region, the source, the drain, and the mitigation region by the well; wherein the high voltage device is a double diffused drain metal oxide semiconductor (DDDMOS) device.

In yet another embodiment, the high voltage device preferably further includes: a first conductive type body region, formed beneath the upper surface, wherein the source is located in the body region; and a first conductive type body electrode, formed in the body region; wherein the high voltage device is a lateral double diffused metal oxide semiconductor (LDMOS) device.

In yet another embodiment, the mitigation region and the LDD region are preferably formed by a common ion implantation process step, wherein: when the second conductive type is N-type, the ion implantation process step is performed by implanting phosphorus ions under accelerated voltage of 30,000-120,000 V and dosage of 1*10¹³-6*10¹³ ions/cm²; and when the second conductive type is P-type, the ion implantation process step is performed by implanting boron ions under accelerated voltage of 10,000-100,000 V and dosage of 1*10¹³-6*10¹³ ions/cm², or by implanting boron fluoride ions under accelerated voltage of 30,000-140,000 V and dosage of 1*10¹³-6*10¹³ ions/cm².

The objectives, technical details, features, and effects of the present invention will be better understood with regard to the detailed description of the embodiments below.

### BRIEF DESCRIPTION OF THE DRAWINGS

FIG. 1 shows a schematic cross-section view of a conventional LDMOS device 100.

FIG. 2 shows a schematic cross-section view of the conventional DDDMOS device 200.

FIG. 3 shows a first embodiment of the present invention.

FIGS. 4A-4F show a second embodiment of the present invention.

FIG. 5 shows a third embodiment of the present invention.

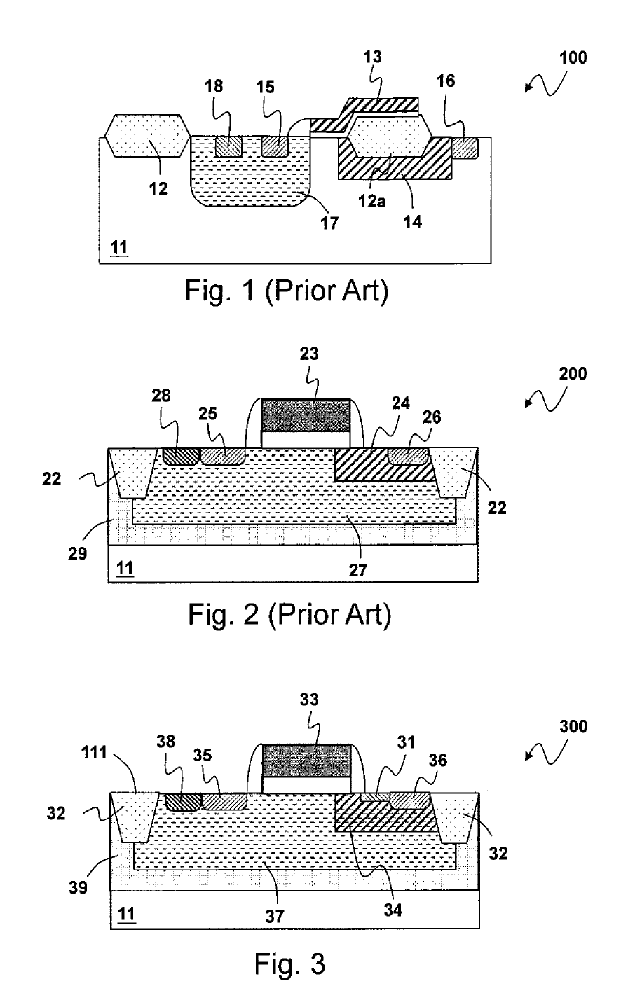

### DESCRIPTION OF THE PREFERRED EMBODIMENTS

The drawings as referred to throughout the description of the present invention are for illustration only, to show the interrelations between the regions and the process steps, but not drawn according to actual scale.

Please refer to FIG. 3 for a first embodiment according to the present invention, wherein a DDDMOS device 300 according to the present invention is illustrated in the figure. As shown in the figure, the DDDMOS device 300 is formed in a substrate 11, and the substrate 11 has an upper surface 111 and isolation regions 32, wherein by the isolation regions 32, the DDDMOS device 300 is electrically isolated from other devices in the substrate 11. The isolation regions 32 are formed, for example, by a LOCOS or STI process (the latter being shown in the figure). The substrate 11 is, for example but not limited to, a P-type substrate (or an N-type substrate in another embodiment). The DDDMOS device 300 includes a gate 33, an N-type drift region 34, an N-type source 35, an N-type drain 36, an N-type isolation region 39, an N-type mitigation 39, a P-type well 37, and a P-type body electrode 38. The gate 33 is formed on the upper surface 111. The N-type drift region 34, the N-type source 35, the N-type drain 36, the N-type isolation region 39, and the N-type mitigation region 31 are formed beneath the upper surface 111 by lithography process steps and ion implantation process steps, wherein the lithography process steps define the implantation regions by photoresist masks and/or together with a self-alignment effect provided by all or part of the gate 33 and the isolation regions 32, and the ion implantation process steps implant N-type impurities to the defined regions in the form of accelerated ions. The P-type well region 37 and the P-type body electrode 38 are formed beneath the upper surface 111 by lithography process steps and ion implantation process steps, wherein the lithography process steps define the implantation regions by photoresist masks and/or together with a self-alignment effect provided by all or part of the gate 33 and the isolation regions 32, and the ion implantation process steps implant P-type impurities to the defined regions in the form of accelerated ions. The source 35 and the drain 36 are beneath the gate 33 and at different sides thereof respectively. The drain 36 is located in the drift region 34, and the drain 36 and the gate 33 are separated by a portion of the drift region 34, and at least part of the drift region 34 is formed below the gate 33. The drift region 34, the source 35, the drain 36, and the mitigation region 31 are located in the isolation region 39. Besides, the isolation region 39 is separated from the drift region 34, the source 35, the drain 36, and the mitigation region 31 by the well 37.

This embodiment is different from the prior art in that, in this embodiment, the DDDMOS device 300 includes the mitigation region 31 formed in the drift region 34, and the mitigation region 31 is located between the gate 33 and the drain 36. The mitigation region is formed by a process step which also forms a lightly doped (LDD) region in the low voltage device in the substrate 11, such that no additional process step is required because the step for forming the LDD region in the low voltage device exists already. In another embodiment, one or more of the N-type isolation region 39, the P-type well 37, and the P-type body electrode 38 may be omitted in a DDDMOS device.

This arrangement has at least the following advantage: the high voltage device of the present invention has a better breakdown voltage while it can be manufactured by a low cost because no additional process step or mask is required.

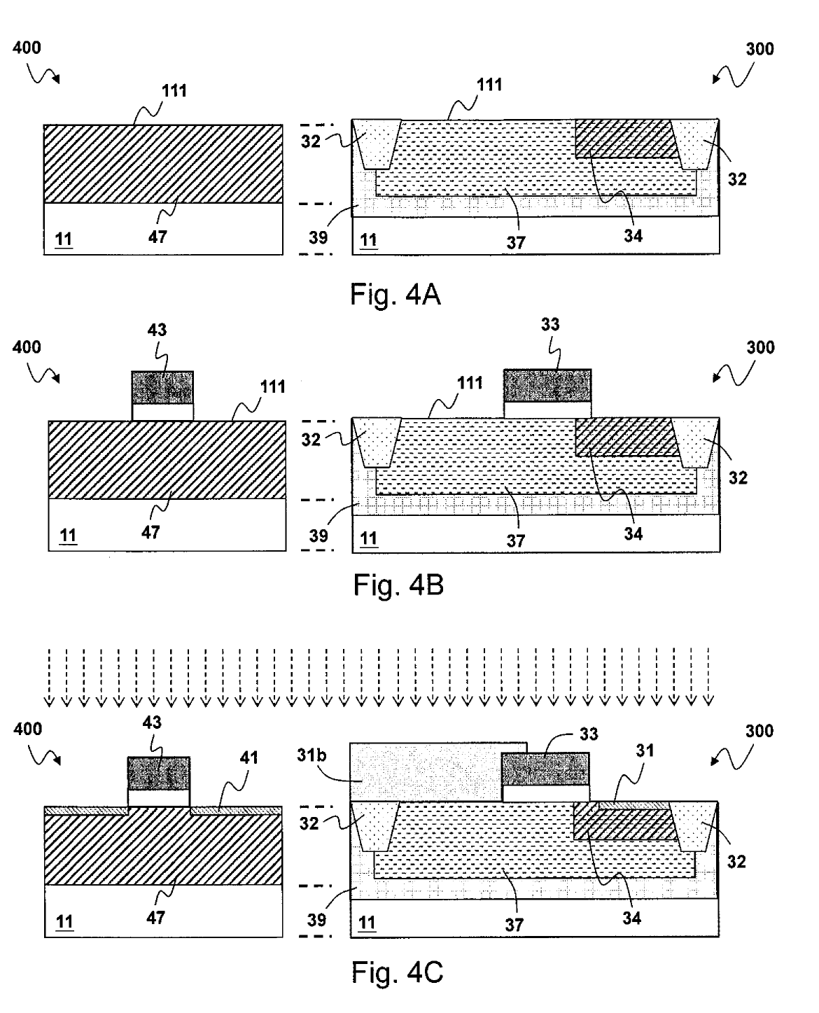

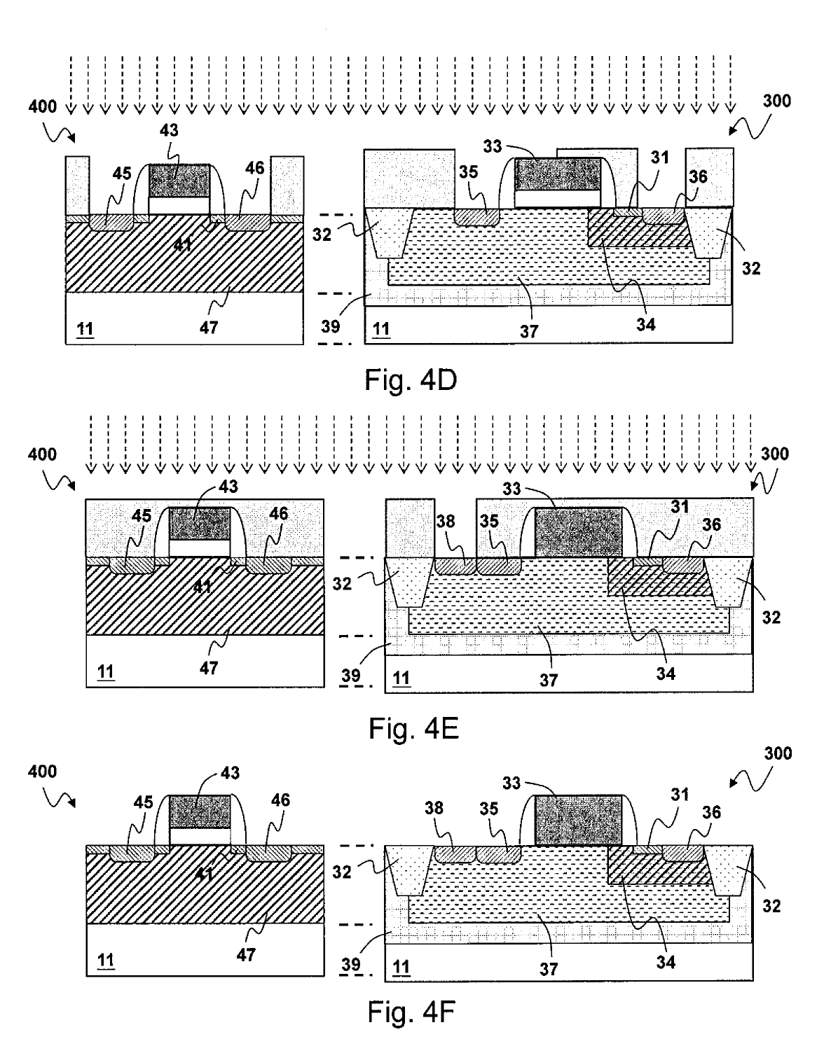

FIGS. 4A-4F show a second embodiment of the present invention. This embodiment illustrates, by way of example, a manufacturing method of a high voltage device of the present invention, by process steps for manufacturing a low voltage device. For better understanding, it is assumed that a low voltage NMOS device 400 and a high voltage device such as the device 300 of the present invention are to be manufactured on the same substrate, which are shown at left and right sides in each figure of FIGS. 4A-4F, and separated by horizontal dashed lines. As shown in FIG. 4A, a P-type substrate 11 is provided, which has an upper surface 111. As shown in the figure, in the P-type substrate 11, a P-type well 47 beneath the upper surface 111 in the low voltage NMOS device 400, and the isolation regions 32, the N-type isolation region 39, the P-type well 37, and the N-type drift region 34 beneath the upper surface 111 in the DDDMOS device 400 are formed respectively.

Next, as shown in FIG. 4B, agate 43 of the low voltage NMOS device 400 and the gate 33 of the DDDMOS device 300 are formed on the upper surface 111 of the substrate 11 respectively.

Next, as shown in FIG. 4C, by common process steps, wherein a lithography process defines the implantation regions of the LDD region 41 of the low voltage NMOS device 400 and the mitigation region 31 of the DDDMOS device 300 by for example but not limited to a photoresist mask 31b or together with other masks or self-alignment effect, and an ion implantation process implants N-type impurities to the defined regions in the form of accelerated ions as indicated by the dashed arrow lines, the LDD region 41 of the low voltage NMOS device 400 and the mitigation region 31 of the DDDMOS device 300 are formed.

Next, as shown in FIG. 4D, by common process steps or different process steps, N-type sources 45 and 35, and N-type drains 46 and 36, are formed in the low voltage NMOS device 400 and the high voltage DDDMOS device 300 respectively. The N-type source 45 and the N-type drain 46 are formed at different sides of the gate 43 beneath the upper surface 111. The source 45 or/and the drain 46 is/are in the LDD region from top view (not shown). The LDD region 41 is for mitigating a hot carrier effect of the low voltage NMOS device 400 in operation.

Next, as shown in FIG. 4E, the P-type body electrode 38 is formed in the high voltage DDDMOS device 300. Last, referring to FIG. 4F, the low voltage NMOS device 400 and the high voltage DDDMOS device 300 are completed.

According to the present invention, the mitigation region 41 and the LDD region 31 are formed by a common ion implantation process step, wherein as preferable embodiments:

when the mitigation region 41 and the LDD region 31 are N-type, the ion implantation process step is performed by implanting phosphorus ions under accelerated voltage of 30,000-120,000 V and dosage of 1*10¹³-6*10¹³ ions/cm²; and

when the mitigation region 41 and the LDD region 31 are P-type, the ion implantation process step is performed by implanting boron ions under accelerated voltage of 10,000-100,000 V and dosage of 1*10¹³-6*10¹³ ions/cm², or by implanting boron fluoride ions under accelerated voltage of 30,000-140,000 V and dosage of 1*10¹³-6*10¹³ ions/cm².

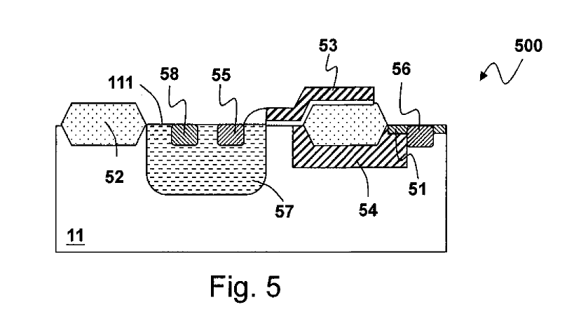

FIG. 5 shows a third embodiment of the present invention. This embodiment is different from the first embodiment in that, this embodiment is a high voltage LDMOS device 500 instead of the high voltage DDDMOS device 300. As shown in the figure, the LDMOS device 500 is formed in substrate 11, and the substrate 11 has an upper surface 111 and multiple isolation regions 52 by which the LDMOS device 500 is electrically isolated from other devices in the substrate 11. The isolation region 52 for example is formed by the STI process or the LOCOS process, the latter being shown in the figure. The substrate 11 for example is a P-type substrate but not limited to the P-type substrate. The LDMOS device 500 includes a gate 53, an N-type drift region 54, an N-type source 55, an N-type drain 56, an N-type mitigation region 51, a P-type body region 57, and a P-type body electrode 58. The N-type drift region 54, the N-type source 55, the N-type drain 56, and the N-type mitigation region 51 are formed by lithography process steps and ion implantation process steps, wherein the lithography process steps define the implantation regions by photoresist masks and/or together with a self-alignment effect provided by all or part of the gate 53 and the isolation regions 52, and the ion implantation process steps implant N-type impurities to the defined regions in the form of accelerated ions. The P-type body region 57 and the P-type body electrode 58 are formed by lithography process steps and ion implantation process steps, wherein the lithography process steps define the implantation regions by photoresist masks and/or together with a self-alignment effect provided by all or part of the gate 53 and the isolation regions 52, and the ion implantation process steps implant P-type impurities to the defined regions in the form of accelerated ions. The source 55 and the drain 56 are beneath the gate 53 and at different sides thereof respectively. The drain 56 and the gate 53 are separated by the drift region 54. The source 55 and the body electrode 58 are formed beneath the upper surface 111 in the body region 57. The mitigation region 51 is located between the gate 53 and the drain 56, and the mitigation region 51 is formed by a process step which also forms an LDD region in the low voltage device in the substrate 11.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device, such as a deep well, etc., can be added. For another example, the lithography step described in the above can be replaced by electron beam lithography, X-ray lithography, etc. For yet another example, the isolation region, the drift region, the source, the drain, the mitigation region in all the aforementioned embodiments are not limited to N-type, and the well, the body region, and the body electrode are not limited to P-type; they may be interchanged, with corresponding adjustments. For another example, the present invention is not limited to the DDDMOS device or the LDMOS device, but it may be any other type of high voltage device. In view of the foregoing, the spirit of the present invention should cover all such and other modifications and variations, which should be interpreted to fall within the scope of the following claims and their equivalents.

What is claimed is:

1. A high voltage device, which is formed in a first conductive type substrate on which is formed a low voltage device, wherein the substrate has an upper surface, the high voltage device comprising:
a drift region formed beneath the upper surface, and doped with second conductive type impurities;
a gate formed on the upper surface, wherein at least part of the drift region is formed below the gate;
a source and a drain, doped with the second conductive type impurities, and formed beneath the upper surface at different sides of the gate, wherein the drain is located in the drift region, and the drain and the gate are separated by a portion of the drift region; and
a mitigation region, doped with the second conductive type impurities, and formed in the drift region, wherein the mitigation region is located between the gate and the drain, and the mitigation region is formed by a process step which also forms a lightly doped (LDD) region in the low voltage device.

2. The high voltage device of claim 1, wherein the low voltage device further includes:
a low voltage gate formed on the upper surface; and
a low voltage source and a low voltage drain, doped with the second conductive type impurities, and formed beneath the upper surface at different sides of the low voltage gate, wherein the low voltage source and/or the low voltage drain are/is located in the LDD region from top view;
wherein the LDD region is for mitigating a hot carrier effect of the low voltage device in operation.

3. The high voltage device of claim 1, further comprising:
a second conductive type isolation region formed beneath the upper surface, wherein the drift region, the source, the drain, and the mitigation region are located in the isolation region; and
a first conductive type well formed in the isolation region, wherein the isolation region is separated from the drift region, the source, the drain, and the mitigation by the well;
wherein the high voltage device is a double diffused drain metal oxide semiconductor (DDDMOS) device.

4. The high voltage device of claim 1, further comprising:
a first conductive type body region, formed beneath the upper surface, wherein the source is located in the body region; and
a first conductive type body electrode, formed in the body region;
wherein the high voltage device is a lateral double diffused metal oxide semiconductor (LDMOS) device.

5. The high voltage device of claim 2, wherein the mitigation region and the LDD region are formed by a common ion implantation process step, wherein:
when the second conductive type is N-type, the ion implantation process step is performed by implanting phosphorus ions under accelerated voltage of 30,000-120,000 V and dosage of 1*10¹³-6*10¹³ ions/cm²; and
when the second conductive type is P-type, the ion implantation process step is performed by implanting boron ions under accelerated voltage of 10,000-100,000 V and dosage of 1*10¹³-6*10¹³ ions/cm², or by implanting boron fluoride ions under accelerated voltage of 30,000-140,000 V and dosage of 1*10¹³-6*10¹³ ions/cm².

6. A manufacturing method of a high voltage device, comprising:
providing a first conductive type substrate for forming the high voltage device and a low voltage device in the substrate, wherein the substrate has an upper surface;
forming a second conductive type drift region beneath the upper surface;
forming agate on the upper surface, wherein at least part of the drift region is formed below the gate;
forming second conductive type source and drain beneath the upper surface at different sides of the gate, wherein the drain is located in the drift region, and the drain and the gate are separated by a portion of the drift region; and
forming a second conductive type mitigation region in the drift region, wherein the mitigation region is located between the gate and the drain, and the mitigation region is formed by a process step which also forms a lightly doped (LDD) region in the low voltage device.

7. The manufacturing method of claim 6, wherein the low voltage device further includes:
a low voltage gate formed on the upper surface; and
a low voltage source and a low voltage drain, doped with the second conductive type impurities, and formed beneath the upper surface at different sides of the low voltage gate, wherein the low voltage source and/or the low voltage drain are/is located in the LDD region from top view;
wherein the LDD region is for mitigating a hot carrier effect of the low voltage device in operation.

8. The manufacturing method of claim 6, further comprising:
forming a second conductive type isolation region beneath the upper surface, wherein the drift region, the source, the drain, and the mitigation region are located in the isolation region; and
forming a first conductive type well beneath the upper surface in the isolation region, wherein the isolation region is separated from the drift region, the source, the drain, and the mitigation region by the well;
wherein the high voltage device is a double diffused drain metal oxide semiconductor (DDDMOS) device.

9. The manufacturing method of claim 6, further comprising:
forming a first conductive type body region beneath the upper surface, wherein the source is located in the body region; and
forming a first conductive type body electrode in the body region;
wherein the high voltage device is a lateral double diffused metal oxide semiconductor (LDMOS) device.

10. The manufacturing method of claim 7, wherein the mitigation region and the LDD region are formed by a common ion implantation process step, wherein:
when the second conductive type is N-type, the ion implantation process step is performed by implanting phosphorus ions under accelerated voltage of 30,000-120,000 V and dosage of 1*10¹³-6*10¹³ ions/cm²; and
when the second conductive type is P-type, the ion implantation process step is performed by implanting boron ions under accelerated voltage of 10,000-100,000 V and dosage of 1*10¹³-6*10¹³ ions/cm², or by implanting boron fluoride ions under accelerated voltage of 30,000-140,000 V and dosage of 1*10¹³-6*10¹³ ions/cm².
